(19) United States
(12) Patent Application Publication
(10) Pub. No.: US 2024/0304564 A1
(43) Pub. Date: Sep. 12, 2024

(54) ELECTRONIC DEVICE AND MANUFACTURING METHOD THEREOF

(71) Applicant: SAMSUNG ELECTRONICS CO., LTD., Suwon-si (KR)

(72) Inventors: Junbae KIM, Suwon-si (KR); Taehwan KIM, Suwon-si (KR); Heejung HWANG, Suwon-si (KR)

(21) Appl. No.: 18/394,974

(22) Filed: Dec. 22, 2023

(30) Foreign Application Priority Data
Mar. 6, 2023 (KR) 10-2023-0028930

(51) Int. Cl. H01L 23/552; H01L 25/00; H01L 25/18; H10B 80/00

(52) U.S. Cl. CPC H01L 23/552; H01L 25/18; H01L 25/50; H10B 80/00; H01L 23/3128; H01L 24/16; H01L 24/32; H01L 24/33; H01L 24/48; H01L 24/73; H01L 2224/16227; H01L 2224/32145; H01L 2224/32225; H01L 2224/33181; H01L 2224/48091; H01L 2224/48227; H01L 2224/73215; H01L 2224/73265

(57) ABSTRACT

An electronic device includes a base substrate; a first package mounted on the base substrate, the first package including a first substrate and a first semiconductor chip mounted on the first substrate; a second package mounted on the first package, the second package including a second substrate, a second semiconductor chip mounted on the second substrate, a sealing material surrounding an upper surface of the second substrate and the second semiconductor chip, and a conformal conductive coating formed on at least an upper surface of the sealing material. A conductive fixing portion is secured to a ground pad exposed at an upper surface of the base substrate. A shielding can is secured to the base substrate by the conductive fixing portion and includes a side portion extending around the first and second packages. A metal paste is formed between the shielding can and the conformal conductive coating to contact the shielding can and the conformal conductive coating.

### CROSS-REFERENCE TO RELATED APPLICATION(S)

This application claims benefit of and priority to Korean Patent Application No. 10-2023-0028930 filed on Mar. 6, 2023 in the Korean Intellectual Property Office, the disclosure of which is incorporated herein by reference in its entirety.

### BACKGROUND

The present disclosure relates to an electronic device and manufacturing method thereof.

In response to high-performance demand of electronic devices, stacking technology of semiconductor packages has been developed, and semiconductor packages are being released in the form of complex packages such as package on package (PoP) packages. For example, a DRAM package and an application processor (AP) package may be integrated into a single semiconductor package.

A semiconductor package incorporated with a device for processing high-frequency signals, such as an AP, may require a shielding structure to alleviate electromagnetic interference (EMI). For example, a shielding structure may be implemented by covering a semiconductor package with a shielding can. The shielding can is formed of a conductive material, and may be mounted on a substrate on which a semiconductor package is mounted and may be connected to a ground portion of the substrate. The shield may remove electromagnetic waves generated by the semiconductor package through the ground portion and may block external electromagnetic waves from affecting the semiconductor package inside the shielding can.

Meanwhile, the shielding structure of the shielding can may make it difficult to dissipate heat generated by an internal semiconductor package.

### SUMMARY

An aspect of the present disclosure is to provide an electronic device having a shielding structure that can effectively shield electromagnetic waves while effectively discharging heat generated by a semiconductor package.

According to an aspect of the present disclosure, an electronic device includes a base substrate; a first package mounted on the base substrate, the first package including a first substrate and a first semiconductor chip mounted on the first substrate; a second package mounted on the first package, the second package including a second substrate, a second semiconductor chip mounted on the second substrate, a sealing material surrounding an upper surface of the second substrate and the second semiconductor chip, and a conformal conductive coating on at least an upper surface of the sealing material. A conductive fixing portion is secured fixed to a ground pad at an upper surface of the base substrate. A shielding can is secured to the base substrate by the conductive fixing portion, the shielding can includes a side portion surrounding the first and second packages. A metal paste is between the shielding can and the conformal conductive coating and contacts the shielding can and the conformal conductive coating.

According to an aspect of the present disclosure, an electronic device includes: a base substrate; a POP package mounted on the base substrate, the POP package including an upper package having a conformal conductive coating on at least an upper surface thereof, and a lower package supporting the upper package A shielding can is electrically connected to a ground pad of the base substrate and is configured to extend around at least a side surface of the POP package, wherein the shielding can includes a window that exposes an upper surface of the conformal conductive coating. A metal material is configured to electrically connect the conformal conductive coating and the shielding can.

According to an aspect of the present disclosure, a manufacturing method of an electronic device includes: forming a conformal shield package by forming a conformal conductive coating on at least an upper surface of an upper package of a POP package, wherein the POP package includes the upper package and a lower package; mounting the conformal shield package on a base substrate; securing a conductive fixing portion to a ground pad of the base substrate; securing a shielding can to the conductive fixing portion so that the shielding can surrounds the conformal shield package; and forming a metal paste in a gap between the shielding can and the conformal conductive coating.

An electronic device according to an example embodiment of the present disclosure can provide an electromagnetic shielding function and improved heat dissipation performance of a semiconductor package by bonding a shielding can exposing an upper surface of a semiconductor package on which a conformal conductive coating is formed, to the conformal conductive coating.

It should be noted that aspects of the present disclosure are not limited to the above-mentioned aspects, and other unmentioned aspects of the present disclosure will be clearly understood by those skilled in the art from the following descriptions.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a cross-sectional view illustrating an electronic device according to an example embodiment of the present disclosure;

FIGS. 2 to 6B are views illustrating a manufacturing process of an electronic device described with reference to FIG. 1;

FIG. 7 is a top view of the electronic device described with reference to FIG. 1; and

FIGS. 8 to 14 are views illustrating an electronic device according to various example embodiments of the present disclosure.

### DETAILED DESCRIPTION

Hereinafter, example embodiments of the present disclosure will be described with reference to the accompanying drawings.

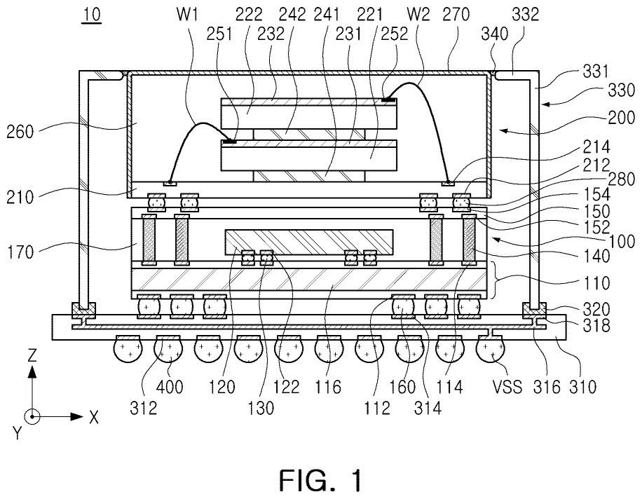

FIG. 1 is a cross-sectional view illustrating an electronic device according to an example embodiment of the present disclosure.

Referring to FIG. 1, an electronic device 10 may include a first package 100, a second package 200, a base substrate 310, a conductive fixing portion 320, a shielding can 330, a metal paste 340, and an external connection member 400.

The first package 100 may include a first semiconductor chip 120, and the second package 200 may include one or more second semiconductor chips 221 and 222. Since the second package 200 is formed on an upper portion of the first package 100, the first package 100 and the second package 200 may constitute a package on package (POP) package. The PoP package may be mounted on the base substrate 310.

The first semiconductor chip 120 may be a logic chip formed in a system on chip (SoC) type. For example, the first semiconductor chip 120 may be an application processor (AP) chip having a system on chip (SoC) type, used in mobile systems, such as mobile phones, MP3 players, navigation, and PMP. Furthermore, the logic chip may be a microprocessor, for example, a central processing unit (CPU), a controller, and an application specific integrated circuit (ASIC).

The second semiconductor chips 221 and 222 may be memory chips such as a dynamic random access memory (DRAM) formed on a second substrate 210. Furthermore, the memory chip may be a double data rate (DDR) chip or synchronous DRAM (SDRAM) chip.

According to an example embodiment of the present disclosure, the second package 200 may include a conformal conductive coating 270 on a surface thereof. According to an example embodiment of the present disclosure, the conformal conductive coating 270, the conductive fixing portion 320, the shielding can 330, and the metal paste 340 may remove electromagnetic waves generated by the POP package including the first package 100 and the second package 200, or may provide an electromagnetic shielding structure to shield electromagnetic waves arriving from the outside. Hereinafter, the electronic device 10 according to an example embodiment of the present disclosure will be described in detail. Referring to FIG. 1, the first package 100 may further include a lower substrate 110, a connection member 140, and an upper substrate 150. The lower substrate 110 may support the first semiconductor chip 120. Pads may be formed on a lower surface and an upper surface of the lower substrate 110. For example, a lower pad 112 may be formed on the lower surface of the lower substrate 110, and an upper pad 114 may be formed on the upper surface of the lower substrate 110.

The upper substrate 150 may be disposed above the first semiconductor chip 120 and may support the second package 200. The upper substrate 150 may include a lower pad 152 and an upper pad 154. Similarly to the lower substrate 110, the upper substrate 150 may include a metal wiring pattern that electrically connects the lower pad 152 and the upper pad 154.

The connection member 140 may support the upper substrate 150, and may be in contact with the upper pad 114 of the lower substrate 110 and the lower pad 152 of the upper substrate 150 so as to electrically connect and mechanically support the lower substrate 110 and the upper substrate 150.

The connection member 140 may be formed of, for example, solder. However, the present disclosure is not limited thereto, and the connection member 140 may be formed of tin (Sn), silver (Ag), copper (Cu), or aluminum (Al). Furthermore, the connection member 140 may be formed in a cylindrical shape, but the present disclosure is not limited thereto, and the connection member 140 may be formed in various forms such as a ball shape, a polygonal pillar, or a polyhedron, and may be formed in a form in which two or more ball shapes are coupled.

The lower substrate 110 and the upper substrate 150 may be formed of silicon, glass, ceramic, or plastic. In this example embodiment of the present disclosure, the lower substrate 110 and the upper substrate 150 are not limited to such a material.

The lower substrate 110 and the upper substrate 150 may be formed based on an active wafer or an interposer substrate. Here, the active wafer refers to a wafer in which a semiconductor chip may be formed, like a silicon wafer. Furthermore, the lower substrate 110 may include a multilayer structure in which metal wiring patterns are formed therein. FIG. 1 illustrates, for example, an interposer 116 that may electrically connect the upper pad 114 to the lower pad 112 through metal wiring patterns.

A chip pad 122 may be formed on a lower surface of the first semiconductor chip 120, and the first semiconductor chip 120 may be mounted on the lower substrate 110 in a flip-chip manner through the connection member 130 attached to the chip pad 122. That is, the connection member 130 may physically and electrically connect the first semiconductor chip 120 and the upper pad 114.

The first package 100 may further include a connection member 160 and a sealing material 170. The connection member 160 may be attached to the lower pad 112 and an upper pad 314 of a base substrate 300 to provide electrical connection between the first package 100 and the base substrate 300.

The sealing material 170 may seal the first semiconductor chip 120 and the connection member 140 between the lower substrate 110 and the upper substrate 150, and strengthen mechanical fixing force of the lower substrate 110 and the upper substrate 150.

The second substrate 210 may support the second semiconductor chips 221 and 222. Pads may be formed on a lower surface and an upper surface of the second substrate 210. For example, a lower pad 212 may be formed on the lower surface of the second substrate 210, and an upper pad 214 may be formed on the upper surface of the second substrate 210. The second substrate 210 may be formed of silicon, glass, ceramic, or plastic. In this example embodiment of the present disclosure, the second substrate 210 is not limited to such a material.

Similarly to the lower substrate 110 and the upper substrate 150 of the first package 100, the second substrate 210 may include an interposer that electrically connects the lower pad 212 and the upper pad 214.

The second package 200 may further include a redistribution layer 231 of the second semiconductor chip 221, a chip pad 251 formed on the redistribution layer 231, and an adhesive layer 241 fixing the second semiconductor chip 221 to the second substrate 210. Furthermore, the upper package 210 may further include a redistribution layer 232 of the second semiconductor chip 222, a chip pad 252 formed on the redistribution layer 232, and an adhesive layer 242 fixing the second semiconductor chip 222 to the second semiconductor chip 221.

The redistribution layers 231 and 232 may include metal wiring patterns for routing electrical signals of the second semiconductor chips 221 and 222. The electrical signals of the second semiconductor chips 221 and 222 may be connected to the chip pads 251 and 252 through the redistribution layers 231 and 232.

The chip pads 251 and 252 may be electrically connected to the upper pad 214 through wires W1 and W2. That is, the second semiconductor chips 221 and 122 may be mounted on the second substrate 210 by a wire bonding method.

For example, an example of the adhesive layers 241 and 242 may include NCF, a UV film, an instant adhesive, a thermosetting adhesive, a laser curing adhesive, an ultrasonic curing adhesive, and NCP.

The second package 200 may further include a sealing material 260, a conformal conductive coating 270, and a connection member 280. The sealing material 260 may seal the second semiconductor chips 221 and 222 and the wires W1 and W2 on the second substrate 210. The sealing material 260 may be formed of a polymer such as resin. For example, the sealing material 260 may be formed of an epoxy molding compound (EMC).

The conformal conductive coating 270 may be formed on a surface of the sealing material 260. Referring to FIG. 1, the conformal conductive coating 270 may be formed on an upper surface and a side surface of the sealing material 260. The conformal conductive coating 270 includes a conductive material and may provide a electromagnetic shielding function of a portion covered by the coating. As a first example, the conformal conductive coating 270 may include silver (Ag). As a second example, the conformal conductive coating 270 may have a structure in which a plurality of conductive materials are stacked, for example, in a structure in which stainless steel (SUS)-copper (Cu)-stainless steel (SUS) are sequentially stacked.

The connection member 280 may be attached to the lower pad 212 of the second package 200 and the upper pad 154 of the first package 100 to provide an electrical connection between the second package 200 and the first package 100.

The base substrate 310 may include a lower pad 312 and an upper pad 314. The upper pad 314 may be attached to the connection member 160 of the first package 100 to provide an electrical connection between the first package 100 and the base substrate 310.

The connection member 400 may be attached to the lower pad 312. An electrical signal applied from the outside to the connection member 400 may be input to the electronic device 10 through the lower pad 312. Alternatively, an electrical signal generated inside the electronic device 10 may be output to the connection member 400 through the lower pad 312. The base substrate 310 may further include a metal wiring pattern electrically connecting the lower pad 312 and the upper pad 314.

The base substrate 310 may further include a ground pad 318 on an upper surface thereof. For example, the connection member 400 may include a ground portion VSS to which an external ground power source is applied. The ground pad 318 may be grounded by being electrically connected to the ground portion VSS through a metal wiring pattern 316.

In FIG. 1, two adjacent ground pads 318 are illustrated in a first direction (X-direction) in parallel with the POP package and an upper surface of the substrate, but the base substrate 310 may include a plurality of ground pads. For example, the ground pads 318 may be formed in a pattern surrounding a region in which a POP package is mounted in the base substrate 310.

The shielding can 330 may surround a side surface of the POP package including the first package 100 and the second package 200, and may provide an electromagnetic shielding function for the side surface thereof.

The shielding can 330 may include a conductive metal. For example, stainless steel may be used as it is as the shielding can 330, and stainless steel having a surface coated with a different material may be used. The shielding can 330 may have rigidity as it is formed in a plate shape having a thickness, and may provide stability to an electromagnetic shielding structure.

The shielding can 330 may be mechanically fixed (i.e., secured) to the base substrate 310 by the conductive fixing portion 320 and may be electrically connected to the ground pad 318. As a first example, as the conductive fixing portion 320 is a clip-type structure formed of a conductive material such as stainless steel, it may clamp the shielding can 330. As a second example, the conductive fixing portion 320 may include a hardened solder and may be adhered to the ground pad 318 and a lower surface of the shielding can 330.

The shielding can 330 may include a side portion 331 and an upper portion 332. The side portion 331 may be formed to surround (i.e. extend around) a region in which the POP package including the first package 100 and the second package 200 is mounted on the base substrate 310. That is, the side portion 331 may form a closed path in an X-Y plane, and may extend from the upper surface of the base substrate 310 in a third direction (Z-direction), perpendicular to the upper surface of the base substrate 310. The upper portion 332 may extend from an upper edge of the side portion 331 and may be in parallel with the upper surface of the base substrate 310.

According to an example embodiment of the present disclosure, the upper portion 332 may have a shape exposing an upper surface of the conformal conductive coating 270 formed in the second package 200. That is, the upper portion 332 may have a window having a size and a shape similar to a size and a shape of an upper surface of the second package 200. In the example of FIG. 1, an upper surface of the upper portion 332 and the upper surface of the conformal conductive coating 270 may be coplanar.

The metal paste 340 may be formed in a gap between the shielding can 330 and the conformal conductive coating 270 to physically bond and electrically connect the shielding can 330 and the conformal conductive coating 270.

According to an example embodiment of the present disclosure, the ground pad 318, the conductive fixing portion 320, the shielding can 330, the conformal conductive coating 270 and the metal paste 340 may form an electromagnetic shielding structure. The structure in which the shielding can 330 and the conformal conductive coating 270 are physically bonded and electrically connected may effectively shield electromagnetic waves.

Specifically, since the shielding can 330 grounded through the ground pad 318 and the conformal conductive coating 270 are electrically connected, the conformal conductive coating 270 may be effectively grounded even if a separate ground treatment is not performed between the conformal conductive coating 270 and the second substrate 210 of the upper semiconductor device 200. The electromagnetic shielding structure according to the example embodiment of the present disclosure may prevent internal electromagnetic interference by removing electromagnetic waves radiated from the first semiconductor chip 120 and the second semiconductor chips 221 and 222 to the conformal conductive coating 270 and the shielding can 330.

Furthermore, because the shielding can 330, the metal paste 340, and the conformal conductive coating 270 completely shield the first semiconductor chip 120 and the second semiconductor chips 221 and 222, the first semiconductor chip 120 and the second semiconductor chips 221 and 222 may be effectively protected from electromagnetic waves arriving from the outside.

According to an example embodiment of the present disclosure, since the conformal conductive coating 270 can be exposed from the shielding can 330, heat dissipation performance may be improved. In general, the conformal conductive coating 270 may have a thickness that is thinner (i.e., less) than a thickness of the shielding can 330, for example, 10 μm, and may have a lower thermal resistance than that of the shielding can 330 due to the thinner thickness. Accordingly, the electromagnetic shielding structure according to this example embodiment of the present disclosure may effectively dissipate heat generated by the first semiconductor chip 120 and the second semiconductor chips 221 and 222 to a surface of the conformal conductive coating 270.

In short, the electromagnetic shielding structure according to an example embodiment of the present disclosure may provide improved electromagnetic shielding performance and heat dissipation performance.

On the other hand, FIG. 1 illustrates an Integrated Fan-Out (InFO) POP structure in which the second package 200 is supported using the upper substrate 150 and electrically connected to the first package 100 through the upper substrate 150, but the shielding structure according to this example embodiment of the present disclosure is not limited to being applied to the InFO POP package. For example, the shielding structure according to this example embodiment of the present disclosure may also be applied to a wire bonding POP package, a flip chip POP package, a Through Mold Via (TMV) POP package, a Fan-Out Wafer Level Package (FO-WLP) POP package, and a Panel Level Package (PLP) POP package.

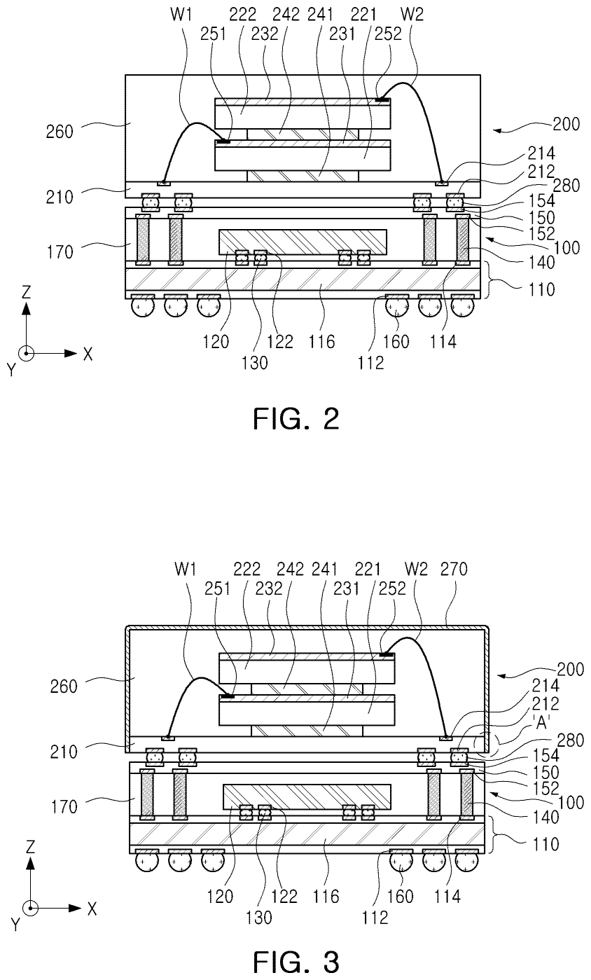

Hereinafter, a manufacturing process of the electronic device 10 described with reference to FIGS. 2 to 6B will be described.

Referring to FIG. 2, the POP package including the first package 100 and the second package 200 is prepared. The structure of the POP package has been described in detail with reference to FIG. 1. Hereinafter, a method of forming the electromagnetic shielding structure for the POP package will be described in detail.

Referring to FIG. 3, the conformal conductive coating 270 may be formed on an upper surface and a side surface of the second package 200.

According to example embodiments, the conformal conductive coating 270 may be formed in various ways. For example, the conformal conductive coating 270 may be formed by a physical vapor deposition (PVD) method of depositing a conductive material, a method of attaching a film formed of a conductive material, or a plating method. Hereinafter, a package in which the first package 100 and the second package 200 form the POP structure and the conformal conductive coating 270 is formed on the second package 200 may be referred to as a conformal shield package.

According to an example embodiment of the present disclosure, the conformal conductive coating 270 may be electrically insulated from a ground of the second package 200 without being connected to a ground pad of the second package 200. For example, referring to region ‘A’ of FIG. 3, the conformal conductive coating 270 may be formed on the POP package in which a separate ground pad is not formed on a side surface of the second substrate 210, or an additional process for electrically connecting the ground of the second package 200 to the conformal conductive coating 270 may not be performed. However, the present disclosure does not exclude a case in which the ground of the second package 200 and the conformal conductive coating 270 are electrically connected. In short, the electromagnetic shielding structure according to example embodiments of the present disclosure may be easily applied to POP packages designed in various ways.

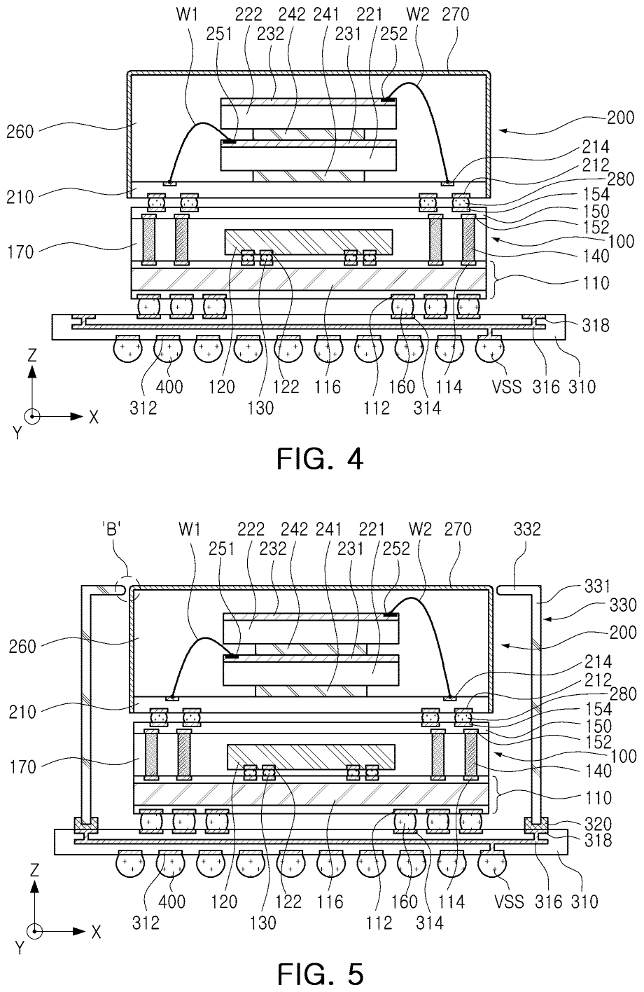

Referring to FIG. 4, the POP package may be mounted on the base substrate 310. For example, a connection member 160 for connecting the lower pad 112 of the first package 100 to the upper pad 314 of the base substrate 310 may be formed by soldering. Meanwhile, as described with reference to FIG. 1, a ground pad 318 electrically connected to the ground portion VSS through the metal wiring pattern 316 may be prepared on the base substrate 310.

Referring to FIG. 5, the conductive fixing portion 320 may be physically fixed (i.e., secured) on the ground pad 318 of the base substrate 310, and the shielding can 330 may be fixed (i.e., secured) to the conductive fixing portion 320.

As a first example, when the conductive fixing portion 320 is a clip-type structure formed of a conductive material, the conductive fixing portion 320 may be attached to the ground pad 318 by the soldering, and a lower portion of the shielding can 330 may be clamped with the conductive fixing portion 320.

As a second example, when the conductive fixing portion 320 is formed of a conductive material such as a solder, the lower surface of the shielding can 330 may be disposed on the ground pad 318 so that the shielding can 330 surrounds the POP package, and the conductive fixing portion 320 may be formed by soldering the lower surface of the shielding can 330 and the ground pad 318.

On the other hand, before the shielding can 330 is fixed (i.e., secured) to the conductive fixing part 320, the side portion 331 may be prepared to have a height similar to that of the POP package mounted on the base substrate 310, and the upper portion 332 may be prepared to have a window having a shape and a size similar to those of the upper surface of the conformal conductive coating 270. However, due to a process error or a design margin of the shielding can 330, a gap may occur between the conformal conductive coating 270 and the window of the shielding can 330. A region ‘B’ of FIG. 5 depicts the gap.

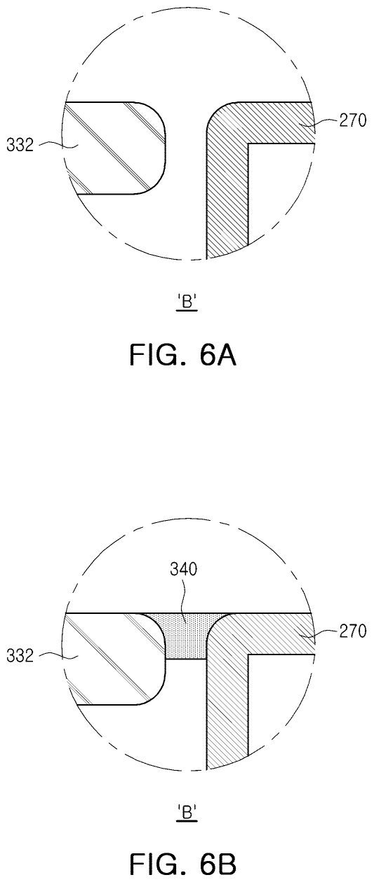

In FIG. 6A, the region ‘B’ of FIG. 5 is enlarged. Referring to FIG. 6A, the conformal conductive coating 270 and the upper portion 332 may be physically and electrically separated due to a gap between the conformal conductive coating 270 and the upper portion 332. When the conformal conductive coating 270 and the upper portion 332 are electrically separated, since the conformal conductive coating 270 is not grounded, it may be difficult to emit electromagnetic waves generated in the POP package. Furthermore, due to the gap between the conformal conductive coating 270 and the upper portion 332, external electromagnetic waves may penetrate into the POP package.

In FIG. 6B, a metal paste 340 may be formed in the gap between the conformal conductive coating 270 and the upper portion 332. For example, the metal paste 340 may be applied between the shielding can 330 and the conformal conductive coating 270 in the form of metal powder particles and may be then hardened by heating. The conformal conductive coating 270 and the upper portion 332 may be physically and electrically connected by the metal paste 340, and the electromagnetic shielding structure of the electronic device 10 as described in FIG. 1 may be completed.

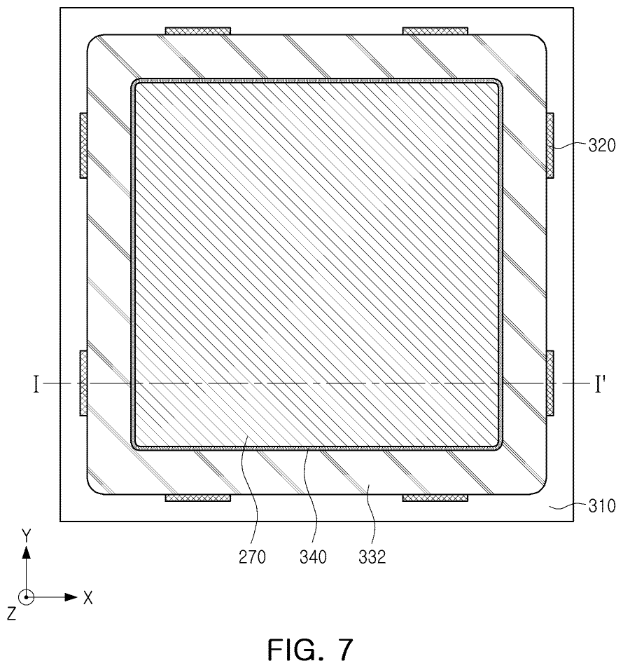

FIG. 7 is a top view of the electronic device described with reference to FIG. 1. FIG. 1 corresponds to a part I-I′ of the electronic device 10 of FIG. 7. FIG. 7 illustrates the base substrate 310 of the electronic device 10, the electrical fixing portion 320, the upper portion 332 of the shielding can, the conformal conductive coating 270 and the metal paste 340.

Referring to FIGS. 1 and 7, the side portion 331 of the shielding can may provide an electromagnetic shielding function on the side surface of the POP package, and the upper portion 332 of the shielding can, the conformal conductive coating 270 and the metal paste 340 may provide an electromagnetic shielding function on the upper surface of the POP package. The electromagnetic shielding structure according to this example embodiment of the present disclosure may physically and electrically shield the POP package without a gap. Accordingly, the electromagnetic shielding structure may effectively prevent external electromagnetic waves from penetrating into the POP package.

Furthermore, the electromagnetic shielding structure may effectively prevent electromagnetic interference by removing electromagnetic waves emitted from the POP package using the ground pad 318 connected through the electrical fixing portion 320. As described with reference to FIG. 3, the conformal conductive coating 270 may not be connected to the ground of the second package 200, but the conformal conductive coating 270 may be grounded by being connected to the ground pad 318 through the metal paste 340. According to this example embodiment of the present disclosure, because a process for connecting the conformal conductive coating 270 to the ground of the second package 200 is not required, process costs may be reduced.

The electromagnetic shielding structure may be formed thinner than the shielding can 330 and may dissipate heat generated by the POP package through the surface of the conformal conductive coating 270 exposed from the shielding can 330. Accordingly, the electromagnetic shielding structure according to the example embodiment of the present disclosure may provide high heat dissipation performance without forming holes to the shielding can 330 that may provide a heat dissipation function but may cause a decrease in the electromagnetic shielding performance. On the other hand, since the conformal conductive coating 270 can be formed on the surface of the second package 200 having support power due to the sealing material 260, the POP package may be protected from a physical impact even if the conformal conductive coating 270 is formed much thinner than the shielding can 330.

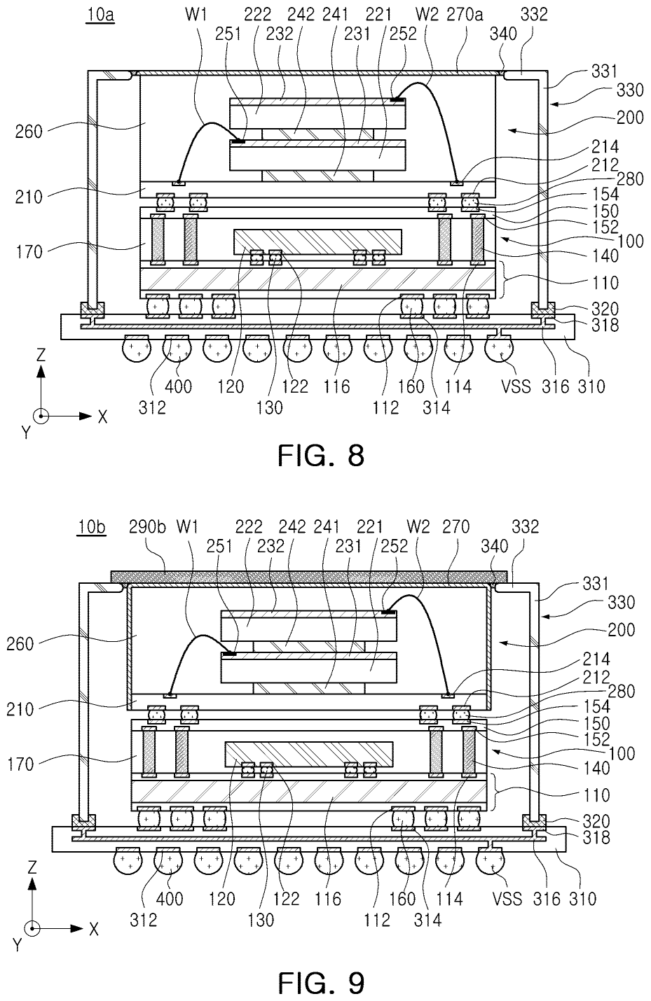

Meanwhile, an example embodiment of the present disclosure is not limited to the electronic device 10 described with reference to FIGS. 1 to 7. Hereinafter, electronic devices according to various embodiments of the present invention will be described with reference to FIGS. 8 to 14.

FIG. 8 illustrates an electronic device 10a according to an example embodiment of the present disclosure. Referring to FIG. 8, the electronic device 10a according to this example embodiment of the present disclosure will be described based on a difference from the electronic device 10 of FIG. 1.

The electronic device 10a may include a conformal conductive coating 270a. Unlike the conformal conductive coating 270 described with reference to FIG. 1, the conformal conductive coating 270a may be formed only on the upper surface of the second package 200. A gap between the conformal conductive coating 270a and the shielding can 330 may be filled with the metal paste 340.

According to an example embodiment of the present disclosure, the conformal conductive coating 270a and the second substrate 210 may not be grounded, and the conformal conductive coating 270a may be grounded by being electrically connected to the shielding can 330 by the metal paste 340. Accordingly, even if the conformal conductive coating 270a is formed only on the upper surface of the second package 200, the electronic device 10a may have an electromagnetic shielding structure having improved heat dissipation performance.

FIG. 9 illustrates an electronic device 10b according to an example embodiment of the present disclosure. Referring to FIG. 9, the electronic device 10b according to this example embodiment of the present disclosure will be described based on a difference from the electronic device 10 of FIG. 1.

Referring to FIG. 9, unlike the electronic device 10 of FIG. 1, the electronic device 10b may further include a thermal interface material (TIM) 290b on the upper portion 332 of the shielding can and the conformal conductive coating 270.

The TIM 290b may be formed of a material that is a mixture of carbon and a polymer, and the polymer may be, for example, a resin-based polymer or an acrylic-based polymer. The TIM 290b may be manufactured as a film and attached to the upper portion 332 and the upper surface of the conformal conductive coating 270, or may be manufactured in a grease form and applied to the upper portion 332 and the upper surface of the conformal conductive coating 270. When the TIM 290b comes into contact with a heat-dissipating plate, an air gap between the electronic device 10b and the heat-dissipating plate may be removed, and heat generated by the POP package may be more effectively discharged through the heat sink.

According to an example embodiment of the present disclosure, the electronic device 10b may meet a height specification required for the electronic device 10b and further improve heat dissipation performance by disposing the TIM 290b having a predetermined thickness. For example, the TIM 290b may be formed to have a thickness of 200 μm to 500 μm in the third direction (Z-direction), perpendicular to the upper surface of the substrate.

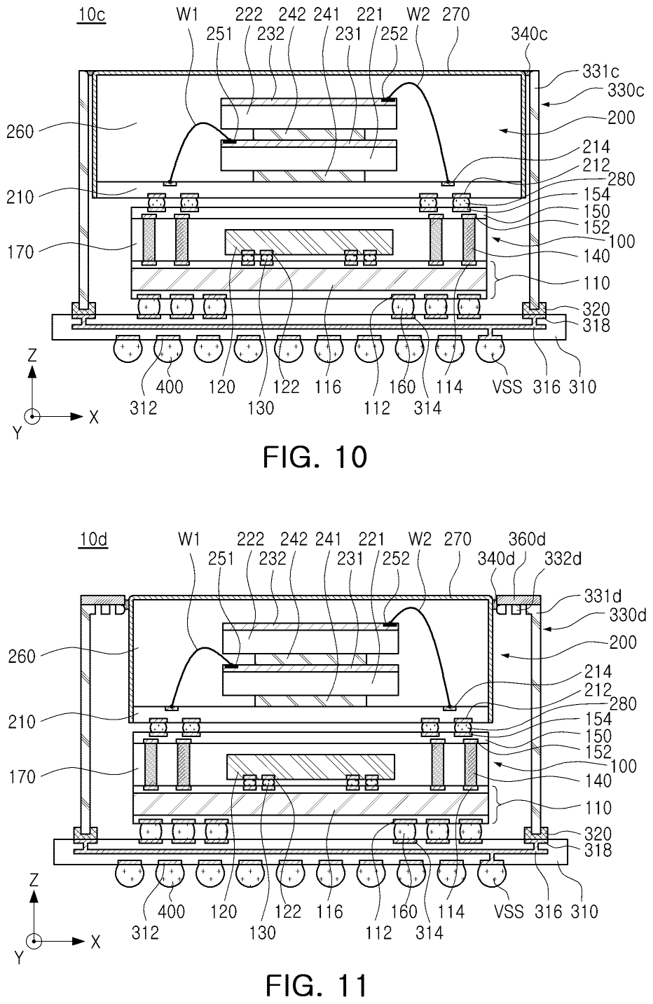

FIG. 10 illustrates an electronic device 10c according to an example embodiment of the present disclosure. Referring to FIG. 10, the electronic device 10c according to an example embodiment of the present disclosure will be described based on a difference from the electronic device 10 of FIG. 1.

Referring to FIG. 10, the electronic device 10c may include a shielding can 330c having only a side portion 331c, unlike the electronic device 10 described with reference to FIG. 1. An internal circumference of the side portion 331c may be similar to an external circumference of the second package 200 on which the conformal conductive coating 270 is formed.

According to an example embodiment of the present disclosure, a gap between the conformal conductive coating 270 and the side portion 331 of the shielding can may be filled by the metal paste 340.

FIG. 11 illustrates an electronic device 10d according to an example embodiment of the present disclosure. Referring to FIG. 11, an electronic device 10d according to this example embodiment of the present disclosure will be described based on a difference from the electronic device 10 of FIG. 1.

A shielding can 330d of the electronic device 10d may include a side portion 331d and an upper portion 332d. Unlike the upper portion 332 described with reference to FIG. 1, the upper portion 332d may include a plurality of holes. The plurality of holes may be provided for heat dissipation.

A metal film 360d may be further attached to an upper surface of the upper portion 332d. For example, the metal film 360d may be formed of copper (Cu), and may include an adhesive surface. The metal film 360d may be formed thicker than the conformal conductive coating 270 but may be formed thinner than the upper portion 332d of the shielding can. For example, the metal film 360d may have a thickness of about 300 μm. The thermal resistance of the metal film 360d may be lower than that of the shielding can 300d.

The metal paste 340d may be applied between the upper portion 332d, the conformal conductive coating, and the metal film 360d. The metal paste 340d may electrically connect the upper portion 332d, the conformal conductive coating, and the metal film 360d.

On the other hand, a height of the shielding can 330d mounted on the base substrate 310 may be lower than the height of the POP package, and an upper surface of the metal film 360d attached to the shielding can 330d may be coplanar with the upper surface of the conformal conductive coating 270.

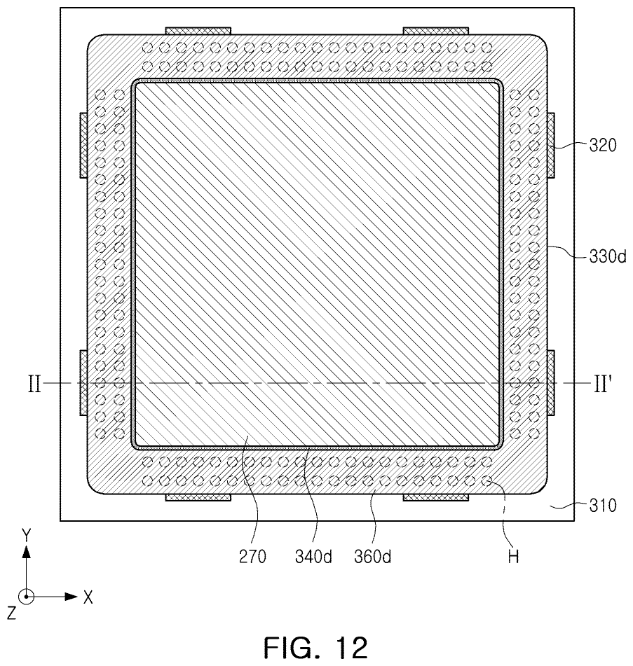

FIG. 12 is a top view of the electronic device 10d described with reference to FIG. 11. FIG. 11 is a cross-sectional view taken along line II-II′ of FIG. 12.

Referring to FIG. 12, a plurality of holes H may be formed in an upper portion of the shielding can. The holes H may be shielded by the metal film 360d.

According to an example embodiment of the present disclosure, the electronic device 10d may have an electromagnetic wave blocking structure including the shielding can 330d, the conformal conductive coating 270, the metal film 360d, and the metal paste 340d. The conformal conductive coating 270 and the metal film 360d may be grounded by being electrically connected to the shielding can 330d, and because the POP package may be tightly shielded from the outside, electromagnetic shielding may be effectively performed.

According to an example embodiment of the present disclosure, the electronic device 10d may have strong fixing force by the shielding can 330d formed of a rigid material, and heat dissipation performance may be further improved by the holes formed in the upper portion 332b and the metal film 360d.

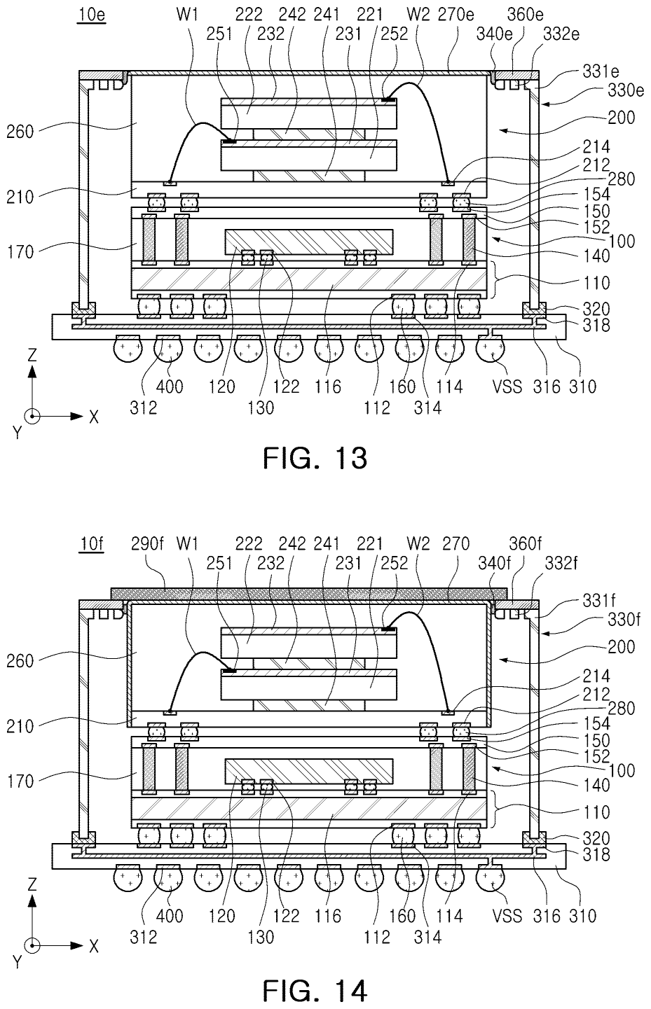

FIG. 13 illustrates an electronic device 10e according to an example embodiment of the present disclosure. Referring to FIG. 13, an electronic device 10e according to this example embodiment of the present disclosure will be described based on a difference from the electronic device 10d of FIG. 11.

According to an example embodiment of the present disclosure, the electronic device 10e may include a conformal conductive coating 270e formed only on the upper surface of the second package 200. Furthermore, the electronic device 10e may include a metal paste 340e that electrically connects an upper portion 332e of a shielding can, a metal film 360e, and the conformal conductive coating 270e. The conformal conductive coating 270e, the metal paste 340e, a shielding can 330e, and the metal film 360e may form an electromagnetic shielding structure.

FIG. 14 illustrates an electronic device 10f according to an example embodiment of the present disclosure. Referring to FIG. 14, the electronic device 10f according to this example embodiment of the present disclosure will be described based on a difference from the electronic device 10d of FIG. 11.

Unlike the electronic device 10d of FIG. 11, the electronic device 10f of FIG. 14 may further include a TIM 290f on a conformal conductive coating 270f and an upper surface of a metal film 360f. According to an example embodiment of the present disclosure, the electronic device 10f may meet a height specification required for the electronic device 10f or may meet a specification for thermal characteristics by disposing the TIM 290f having a predetermined thickness.

According to an example embodiment of the present disclosure, the electronic device includes a POP package including an upper package having a conformal conductive coating formed on at least an upper surface thereof and a lower package supporting the upper package, a base substrate on which the POP package is mounted, a shielding can electrically connected to a ground pad of the base substrate and configured to surround at least a side surface of the PoP package and having a window exposing an upper surface of the conformal conductive coating, and a metal material configured to electrically connect the conformal conductive coating and the shielding can.

The shielding can, the conformal conductive coating, and the metal paste may provide improved electromagnetic shielding by physically and electrically shielding the POP package from the outside. Furthermore, the conformal conductive coating may be formed thinner than the shielding can, and the shielding can may expose the conformal conductive coating, thereby improving heat dissipation performance of the electronic device. On the other hand, because the conformal conductive coating can be formed on a surface of the upper package having support power, the conformal conductive coating may have sufficient strength to protect the POP package from the physical impact even if it is formed much thinner than the shielding can.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. An electronic device comprising:
a base substrate;
a first package mounted on the base substrate, the first package comprising a first substrate and a first semiconductor chip mounted on the first substrate;
a second package mounted on the first package, the second package comprising a second substrate, a second semiconductor chip mounted on the second substrate, a sealing material surrounding an upper surface of the second substrate and the second semiconductor chip, and a conformal conductive coating on at least an upper surface of the sealing material;
a conductive fixing portion secured to a ground pad at an upper surface of the base substrate;
a shielding can secured to the base substrate by the conductive fixing portion, the shielding can comprising a side portion surrounding the first and second packages; and
a metal paste between the shielding can and the conformal conductive coating, wherein the metal paste contacts the shielding can and the conformal conductive coating.

2. The electronic device of claim 1, wherein the shielding can further comprises:
an upper portion extending from the side portion,
wherein the upper portion comprises a window that exposes an upper surface of the conformal conductive coating.

3. The electronic device of claim 2, wherein an upper surface of the upper portion and the upper surface of the conformal conductive coating are coplanar.

4. The electronic device of claim 2, further comprising:
a thermal interface material (TIM) configured to cover at least a portion of an upper surface of the upper portion and the upper surface of the conformal conductive coating.

5. The electronic device of claim 4, wherein the TIM comprises a mixture of carbon and polymer.

6. The electronic device of claim 2, wherein the upper portion further comprises a plurality of holes formed therethrough.

7. The electronic device of claim 6, further comprising:
a metal film attached to an upper surface of the upper portion.

8. The electronic device of claim 7, wherein the metal paste is in contact with the metal film.

9. The electronic device of claim 7, wherein an upper surface of the metal film and the upper surface of the conformal conductive coating are coplanar.

10. The electronic device of claim 7, wherein a thickness of the metal film is greater than a thickness of the conformal conductive coating, and wherein the thickness of the metal film is less than a thickness of the upper portion.

11. The electronic device of claim 1, wherein the side portion extends from an upper surface of the base substrate in a direction that is perpendicular to the upper surface of the base substrate.

12. The electronic device of claim 1, wherein the conformal conductive coating comprises silver (Au) or has a structure in which stainless steel-copper (Cu)-stainless steel are sequentially stacked.

13. The electronic device of claim 1, wherein the conformal conductive coating is in further contact with a side surface of the sealing material.

14. The electronic device of claim 1, wherein the conformal conductive coating extends to a side surface of the second substrate and is electrically insulated from a ground pad of the second substrate.

15. The electronic device of claim 1, wherein the conductive fixing portion is a clip-type structure that clamps the shielding can, or is solder soldered between the shielding can and the ground pad.

16. The electronic device of claim 1, wherein the ground pad comprises a plurality of ground pads that extend around a region in which the first and second packages are mounted on the base substrate.

17. The electronic device of claim 1, wherein the base substrate comprises a connection member on a lower surface thereof, and further comprising a metal wiring pattern that electrically connects the connection member to the ground pad.

18. The electronic device of claim 1, wherein the first semiconductor chip is an application processor (AP), and
the second semiconductor chip is a DRAM.

19. An electronic device comprising:
a base substrate;
a package on package (POP) package mounted on the base substrate, the POP package comprising an upper package having a conformal conductive coating on at least an upper surface thereof, and a lower package supporting the upper package;
a shielding can electrically connected to a ground pad of the base substrate and configured to extend around at least a side surface of the POP package, the shielding can comprising a window that exposes an upper surface of the conformal conductive coating; and
a metal material configured to electrically connect the conformal conductive coating and the shielding can.

20. A manufacturing method for an electronic device, the method comprising:
forming a conformal shield package by forming a conformal conductive coating on at least an upper surface of an upper package of a POP package, wherein the POP package comprises the upper package and a lower package;
mounting the conformal shield package on a base substrate;
securing a conductive fixing portion to a ground pad of the base substrate;
securing a shielding can to the conductive fixing portion so that the shielding can surrounds the conformal shield package; and
forming a metal paste in a gap between the shielding can and the conformal conductive coating.
